(19) United States
(12) Patent Application Publication
(10) Pub. No.: US 2020/0136595 A1
(43) Pub. Date: Apr. 30, 2020

(54) SCHMITT TRIGGER CIRCUIT WITH INDEPENDENT CONTROL OVER HIGH AND LOW TRIP POINTS USING A SPLIT ARCHITECTURE

(71) Applicant: STMicroelectronics International N.V., Schiphol (NL)

(72) Inventor: Manish GARG, New Delhi (IN)

(73) Assignee: STMicroelectronics International N.V., Schiphol (NL)

(21) Appl. No.: 16/662,506

(22) Filed: Oct. 24, 2019

Related U.S. Application Data
(60) Provisional application No. 62/751,837, filed on Oct. 29, 2018.

(51) Int. Cl. H03K 3/037; H03K 17/687

(52) U.S. Cl. CPC H03K 3/0377; H03K 17/6872

(57) ABSTRACT

A Schmitt trigger circuit includes separate circuits for monitoring change in input signal voltage level in comparison to a low threshold to generate a change in logic state of a first control signal in response to a decrease in a voltage level of the input signal and in comparison to a high threshold to generate a change in logic state of a second control signal in response to an increase in the voltage level of the input signal. A first transistor has a source-drain path connected between a supply node and an output node, with a control terminal of the first transistor configured to receive the second control signal. A second transistor has a source-drain path connected between the output node and a ground node, with a control terminal of the second transistor configured to receive said first control signal.

### CROSS-REFERENCE TO RELATED APPLICATION

This application claims priority from U.S. Provisional Application for Patent No. 62/751,837 filed Oct. 29, 2018, the disclosure of which is incorporated by reference.

### TECHNICAL FIELD

The present invention generally relates to a Schmitt trigger circuit and, in particular, to a Schmitt trigger circuit having independent control over high and low trip points by use of a split Schmitt architecture.

### BACKGROUND

FIG. 1 shows a circuit diagram for a conventional Schmitt trigger circuit 10. An input node 12 is connected to the gate terminals of four metal oxide semiconductor field effect transistors (MOSFETs) whose source-drain paths are connected in series with each other between a positive supply node Vdd and a ground node Gnd. The four MOSFETs include: a p-channel transistor 14 having a source terminal connected to the positive supply node Vdd and a drain terminal connected to node 16; a p-channel transistor 18 having a source terminal connected to node 16 and a drain terminal connected to node 20; an n-channel transistor 22 having drain terminal connected to node 20 and a source terminal connected to node 24; and an n-channel transistor 26 having drain terminal connected to node 24 and a source terminal connected to the ground node Gnd. The Schmitt trigger circuit 10 further includes a p-channel MOSFET feedback transistor 30 and an n-channel MOSFET feedback transistor 32. A source-drain path of the p-channel feedback transistor 30 is connected between node 16 and the ground node. The gate terminal of transistor 30 is connected to node 20 and transistor 30 operates to apply a feedback voltage VP to node 16 in response to the voltage at node 20. A source-drain path of the n-channel feedback transistor 32 is connected between node 24 and the positive supply node Vdd. The gate terminal of transistor 32 is connected to node 20 and transistor 32 operates to apply a feedback voltage VN to node 24 in response to the voltage at node 20. The Schmitt trigger circuit 10 still further includes a complementary metal oxide semiconductor (CMOS) inverter circuit 40 formed by a pair of MOSFETs whose source-drain paths are connected in series with each other between the positive supply node Vdd and the ground node Gnd. The pair of MOSFETs include: a p-channel transistor 42 having a source terminal connected to the positive supply node Vdd and a drain terminal connected to node 44; and an n-channel transistor 46 having drain terminal connected to node 44 and a source terminal connected to the ground node Gnd. The gate terminals of the transistors 42 and 46 are connected to node 20.

The input node 12 receives an input signal IN. Starting with the input signal IN at a logic low level (Gnd voltage), the transistors 14 and 18 are turned on (and transistors 22 and 26 are both turned off) and the signal V at node 20 is at the logic high level (Vdd voltage). The feedback transistor 32 is also turned on to apply the feedback voltage VN at the logic high level to node 24 at the source of transistor 22. Transistor 46 of the inverter 40 is turned on and the output signal OUT is at logic low level.

As the voltage of the input signal IN begins to rise toward the logic high level, the threshold voltage Vt of transistor 26 is exceeded, transistor 26 begins to turn on and the voltage at node 20 begins to fall. A first trip point (referred to as the VIH trip point) of the Schmitt trigger circuit 10 is reached when the voltage of the input signal IN rises to a level where the transistor 22 turns on (i.e., where the gate voltage exceeds the threshold voltage Vth of transistor 22). At this point, the transition of the signal V at node 20 to the logic low level occurs quickly causing the feedback transistor 32 to turn off. Transistor 42 of inverter 40 is turned on and the output signal OUT transitions to the logic high level.

With the input signal IN now at a logic high level, the transistors 22 and 26 are turned on (and transistors 14 and 18 are both turned off) and the signal V at node 20 is at logic low level. The feedback transistor 30 is also turned on to apply the feedback voltage VP at the logic low level to node 16 at the source of transistor 18. Transistor 42 of inverter 40 is turned on and the output signal OUT is at logic high level.

As the voltage of the input signal IN begins to fall toward the logic low level, the threshold voltage of transistor 14 is exceeds, transistor 14 begins to turn on and the voltage at node 16 begins to rise. A second trip point (referred to as the VIL trip point) of the Schmitt trigger circuit 10 is reached when the voltage of the input signal IN falls to a level where the transistor 18 turns on (i.e., where the gate voltage exceeds the threshold voltage Vth of transistor 18). At this point, the transition of the signal V at node 20 to the logic high level occurs quickly causing the feedback transistor 30 to turn off. Transistor 46 of inverter 40 is turned on and the output signal OUT transitions to the logic low level.

### SUMMARY

In an embodiment, a circuit comprises: a low threshold control circuit having an input that receives an input signal and an output the generates a first control signal, said low threshold control circuit configured to respond to a decrease in a voltage level of the input signal to be less than or equal to a low voltage trip point by changing a logic state of the first control signal; a high threshold control circuit having an input that receives the input signal and an output the generates a second control signal, said high threshold control circuit configured to respond to an increase in the voltage level of the input signal to be greater than or equal to a high voltage trip point by changing a logic state of the second control signal; a first transistor having a source-drain path connected between a supply node and an output node, said first transistor having a control terminal configured to receive said second control signal; and a second transistor having a source-drain path connected between the output node and a ground node, said second transistor having a control terminal configured to receive said first control signal.

In an embodiment, a method comprises: driving a gate terminal of an n-channel MOSFET with a first control signal; driving a gate terminal of a p-channel MOSFET with a second control signal; wherein drains of the n-channel MOSFET and the p-channel MOSFET are connected to an output node generating an output signal; in response to a decrease in a voltage level of an input signal to be less than or equal to a low voltage trip point, changing a logic state of the first control signal; and in response to an increase in the voltage level of the input signal to be greater than or equal to a high voltage trip point, changing a logic state of the second control signal.

In an embodiment, a circuit comprises a low threshold control circuit and a high threshold control circuit. The low threshold control circuit includes: a first p-channel transistor having a gate terminal configured to receive an input signal; a second p-channel transistor having a gate terminal configured to receive the input signal; a first n-channel transistor having a gate terminal configured to receive the input signal; wherein source-drain paths of the first p-channel transistor, the second p-channel transistor and the first n-channel transistor are connected in series; and wherein a first control signal is generated at a first node that is connected to drains of the second p-channel transistor and the first n-channel transistor. The high threshold control circuit includes: a third p-channel transistor having a gate terminal configured to receive the input signal; second n-channel transistor having a gate terminal configured to receive the input signal; a third n-channel transistor having a gate terminal configured to receive the input signal; wherein source-drain paths of the third p-channel transistor, the second n-channel transistor and the third n-channel transistor are connected in series; and wherein the second control signal is generated at a second node connected to drains of the third p-channel transistor and the second n-channel transistor. A fourth p-channel transistor has a source-drain path connected between a supply node and an output node, said fourth p-channel transistor having a control terminal configured to receive said second control signal. A fourth n-channel transistor has a source-drain path connected between the output node and a ground node, said fourth n-channel transistor having a control terminal configured to receive said first control signal.

### BRIEF DESCRIPTION OF THE DRAWINGS

For a better understanding of the embodiments, reference will now be made by way of example only to the accompanying figures in which:

FIG. 1 is a circuit diagram for a conventional Schmitt trigger circuit; and

FIG. 2 is a circuit diagram for a Schmitt trigger circuit with split control over trip points.

### DETAILED DESCRIPTION

Reference is now made to FIG. 2 which shows a circuit diagram for a Schmitt trigger circuit 100 with split control over trip points. An input node 112 is connected to the input of a low threshold control circuit 102 (for setting the VIL trip voltage) and to the input of a high threshold control circuit 104 (for setting the VIH trip voltage).

The input node 112 of the low threshold control circuit 102 is connected to the gate terminals of three metal oxide semiconductor field effect transistors (MOSFETs) whose source-drain paths are connected in series with each other between a positive supply node Vdd and a ground node Gnd. The three MOSFETs include: a p-channel transistor 114 having a source terminal connected to the positive supply node Vdd and a drain terminal connected to node 116; a p-channel transistor 118 having a source terminal connected to node 116 and a drain terminal connected to node 120; and an n-channel transistor 122 having drain terminal connected to node 120 and a source terminal connected to the ground node Gnd. The low threshold control circuit 102 further includes a p-channel MOSFET feedback transistor 124 having a source-drain path connected between node 116 and the ground node. The gate terminal of feedback transistor 124 is connected to node 120 and transistor 124 operates to apply a feedback voltage VP to node 116 in response to the voltage at node 120.

The input node 112 of the high threshold control circuit 104 is connected to the gate terminals of three MOSFETs whose source-drain paths are connected in series with each other between the positive supply node Vdd and the ground node Gnd. The three MOSFETs include: a p-channel transistor 134 having a source terminal connected to the positive supply node Vdd and a drain terminal connected to node 136; an n-channel transistor 138 having a source terminal connected to node 136 and a drain terminal connected to node 140; and an n-channel transistor 142 having drain terminal connected to node 140 and a source terminal connected to the ground node Gnd. The high threshold control circuit 104 further includes an n-channel MOSFET feedback transistor 144 having a source-drain path connected between node 140 and the positive supply node Vdd. The gate terminal of feedback transistor 144 is connected to node 136 and transistor 144 operates to apply a feedback voltage VN to node 140 in response to the voltage at node 136.

The Schmitt trigger circuit 100 further includes a pair of MOSFETs whose source-drain paths are connected in series with each other between the positive supply node Vdd and the ground node Gnd. The pair of MOSFETs include: a p-channel transistor 152 having a source terminal connected to the positive supply node Vdd and a drain terminal connected to node 154; and an n-channel transistor 156 having drain terminal connected to node 154 and a source terminal connected to the ground node Gnd. The gate terminal of transistor 152 is connected to receive signal VHT from node 136 and the gate terminal of transistor 156 is connected to receive signal VLT from node 120.

A latch circuit 160 formed by a pair of cross-coupled CMOS logic inverters 162 and 162 is connected to node 154. More specifically, the input of the first inverter 162 is connected to node 154 and the output of the second inverter 164 is connected to node 154. The output of the first inverter 162 is connected to the input of the second inverter 164.

The input node 112 receives an input signal IN. Starting with the input signal IN at a logic low level (Gnd voltage), transistors 114 and 118 of the low threshold control circuit 102 are turned on and transistors 134 and 144 of the high threshold control circuit 104 are turned on. The signals VLT, VHT and VN are all at the logic high level (Vdd voltage). Transistor 156 is turned on and the output signal OUT at node 154 is at the logic low level and is latched at that state by the latch circuit 160. Transistors 122, 124, 138, 142 and 152 are turned off.

As the voltage of the input signal IN begins to rise toward the logic high level and the threshold voltage Vth of transistor 122 is exceeded, transistor 122 turns on and the voltage at node 120 is driven to the logic low state. As a result, the transistor 156 turns off and the drains of transistors 152 and 156 at node 154 are in the high impedance state. The operation of the latch 160, however, maintains the voltage on node 154 at the logic low level.

The rise in voltage of the input signal IN further causes transistor 142 to begin to turn on and the voltage at node 140 begins to fall. A first trip point (referred to as the VIH trip point) of the Schmitt trigger circuit 100 is reached when the voltage of the input signal IN rises to a level where the transistor 138 turns on (i.e., where the gate voltage exceeds the threshold voltage Vth of transistor 138). At this point, the transition of the signal VHT at node 136 to the logic low level occurs quickly causing the feedback transistor 144 to turn off. Transistor 152 is turned on and the output signal OUT transitions to the logic high level.

With the input signal now at the logic high level, transistors 122 and 124 of the low threshold control circuit 102 are turned on and transistors 138 and 142 of the high threshold control circuit 104 are turned on. The signals VLT, VHT and VP are all at the logic low level. Transistor 152 is turned on and the output signal OUT at node 154 is at the logic high level and is latched at that state by the latch circuit 160. Transistors 114, 118, 134, 144 and 156 are turned off.

As the voltage of the input signal IN begins to fall toward the logic low level and the threshold voltage Vth of transistor 134 is exceeded, transistor 134 turns on and the voltage at node 136 is driven to the logic high state. As a result, the transistor 152 turns off and the drains of transistors 152 and 156 at node 154 are in the high impedance state. The operation of the latch 160, however, maintains the voltage on node 154 at the logic high level.

The fall in voltage of the input signal IN further causes transistor 114 to begin to turn on and the voltage at node 116 begins to rise. A second trip point (referred to as the VIL trip point) of the Schmitt trigger circuit 100 is reached when the voltage of the input signal IN falls to a level where the transistor 118 turns on (i.e., where the gate voltage exceeds the threshold voltage Vth of transistor 118). At this point, the transition of the signal VLT at node 120 to the logic high level occurs quickly causing the feedback transistor 124 to turn off. Transistor 156 is turned on and the output signal OUT transitions to the logic low level.

With the input signal IN now at the logic low level, transistors 114 and 118 of the low threshold control circuit 102 are turned on and transistors 134 and 144 of the high threshold control circuit 104 are turned on. The signals VLT, VHT and VN are all at the logic high level. Transistor 156 is turned on and the output signal OUT at node 154 is at the logic low level and is latched at that state by the latch circuit 160. Transistors 122, 124, 138, 142 and 152 are turned off.

The following table summarizes operation of the Schmitt trigger circuit 100:

| IN voltage change | VHT | VLT | Node 154 | Comments |
|---|---|---|---|---|
| Gnd → <Vth122 | Vdd | Vdd | Gnd | T156 On |
| Vth122 → <Vth138 | Vdd | Gnd | Gnd | Latch hold at Gnd |
| Vth138 → Vdd | Gnd | Gnd | Vdd | VIH = Vth138 |
| Vdd → <Vth134 | Gnd | Gnd | Vdd | T152 On |
| Vth134 → <Vth118 | Vdd | Gnd | Vdd | Latch hold at Vdd |
| Vth118 → Gnd | Vdd | Vdd | Gnd | VIL = Vth118 |

It is important that the VLT and VHT signals be controlled by the low threshold control circuit 102 and high threshold control circuit 104, respectively, so as to avoid an operational situation where transistor 152 and transistor 156 are both on at the same time. This is accomplished by designing the transistors of the low threshold control circuit 102 and high threshold control circuit 104 to ensure that Vth138 exceeds Vth122 by a minimum safety margin (for example, 100 mV) and that Vth134 is less than Vth118 by the minimum safety margin.

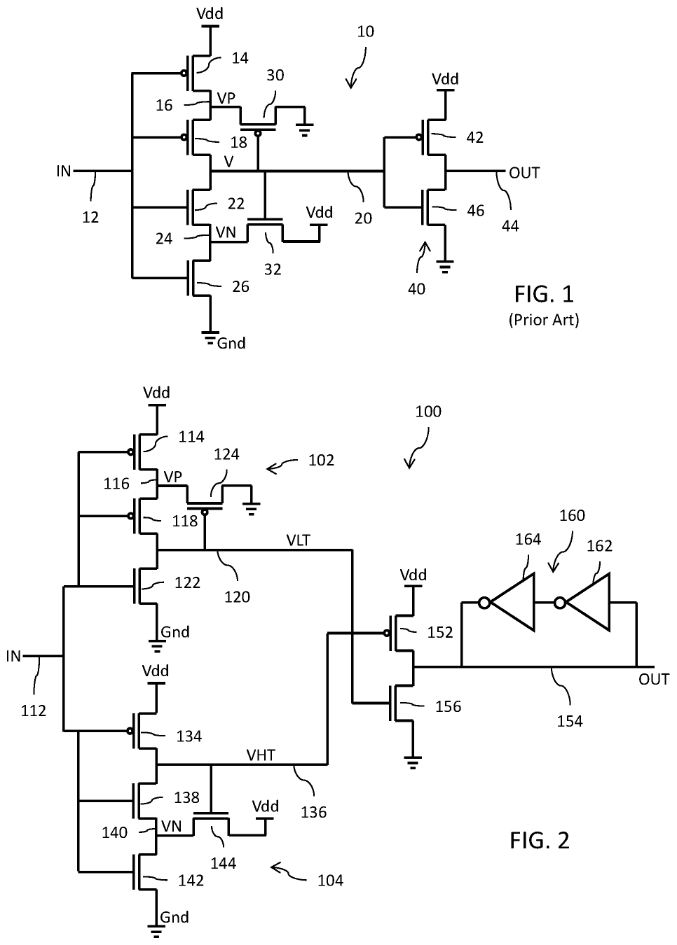

An advantage of the Schmitt trigger circuit 100 over the Schmitt trigger circuit 10 is that a high hysteresis is achieved by reducing overall hysteresis spread without compromising standard requirements (for example, Jedec) for safe VIH/VIL margins. The following table compares circuit operation:

| | | | | Min | Min | Max | |
|---|---|---|---|---|---|---|---|
| Schmitt | Min | Max | Hysteresis | VIH | VIL | Propagation | % Duty- |
| Circuit | Hysteresis | Hysteresis | Spread | Margin | Margin | Delay | Cycle |
| Design | (mV) | (mV) | (max/min) | (mV) | (mV) | (ns) | Spread |
| FIG. 1 | 197 | 350 | 1.78 | 33 | 31 | 0.893 | 49.1-51.3 |
| FIG. 2 | 253 | 321 | 1.27 | 32 | 32.4 | 0.882 | 48.9-50.7 |

The foregoing table shows that, in comparison to the FIG. 1 circuit, the Schmitt trigger circuit 100 of FIG. 2 provides for 28% higher hysteresis and an overall process, voltage and temperature (PVT) spread reduction of 29%, while providing similar propagation delay and duty-cycle.

In the Schmitt trigger circuit 10 of FIG. 1, the trip voltages VIL and VIH are tied to each other by the configuration and operation of the circuit with transistors 14, 18, 22, 26, 30 and 32. Conversely, in the Schmitt trigger circuit 100 of FIG. 2, the trip voltages VIL and VIH are decoupled from each other because each trip voltage is controlled by the configuration of a different circuit (i.e., the low threshold control circuit 102 controls the setting of the VIL trip and the high threshold control circuit 104 controls the setting of the VIH trip).

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A circuit, comprising:
a low threshold control circuit having an input that receives an input signal and an output the generates a first control signal, said low threshold control circuit configured to respond to a decrease in a voltage level of the input signal to be less than or equal to a low voltage trip point by changing a logic state of the first control signal;
a high threshold control circuit having an input that receives the input signal and an output the generates a second control signal, said high threshold control circuit configured to respond to an increase in the voltage level of the input signal to be greater than or equal to a high voltage trip point by changing a logic state of the second control signal;
a first transistor having a source-drain path connected between a supply node and an output node, said first transistor having a control terminal configured to receive said second control signal; and
a second transistor having a source-drain path connected between the output node and a ground node, said second transistor having a control terminal configured to receive said first control signal.

2. The circuit of claim 1, further comprising a latch circuit having a first latch node connected to the output node.

3. The circuit of claim 2, wherein the latch circuit comprises:
a first inverter circuit having an input connected to the output node; and
a second inverter circuit having an output connected to the output node;
wherein an output of the first inverter circuit is connected to an input of the second inverter circuit.

4. The circuit of claim 1, wherein the high voltage trip point is greater than the low voltage trip point.

5. The circuit of claim 1, wherein the first control signal changes logic state from a first logic state to a second logic state when the voltage level of the input signal decreases to be less than or equal to the low voltage trip point and wherein the second control signal changes from the first logic state to the second logic state when the voltage level of the input signal decreases to be less than or equal to a first voltage, said first voltage being greater than the low voltage trip point.

6. The circuit of claim 5, wherein the first logic state is logic low, the second logic state is logic high, the first transistor is a p-channel MOSFET and the second transistor is an n-channel MOSFET.

7. The circuit of claim 1, wherein the second control signal changes logic state from a second logic state to a first logic state when the voltage level of the input signal increases to be greater than or equal to the high voltage trip point and wherein the first control signal changes from the second logic state to the first logic state when the voltage level of the input signal increases to be greater than or equal to a second voltage, said second voltage being less than the high voltage trip point.

8. The circuit of claim 7, wherein the first logic state is logic low, the second logic state is logic high, the first transistor is a p-channel MOSFET and the second transistor is an n-channel MOSFET.

9. The circuit of claim 1, wherein the low threshold control circuit comprises:
a first p-channel transistor having a gate terminal configured to receive the input signal;
a second p-channel transistor having a gate terminal configured to receive the input signal;
an n-channel transistor having a gate terminal configured to receive the input signal;
wherein source-drain paths of the first p-channel transistor, the second p-channel transistor and the n-channel transistor are connected in series; and
wherein the first control signal is generated at drains of the second p-channel transistor and the n-channel transistor connected to the output of the low threshold control circuit.

10. The circuit of claim 9, wherein the low threshold control circuit further comprises a feedback transistor having a source-drain path connected between a ground node and a node between the first p-channel transistor and the second p-channel transistor, said feedback transistor having a control terminal configured to receive the first control signal.

11. The circuit of claim 1, wherein the high threshold control circuit comprises:
a p-channel transistor having a gate terminal configured to receive the input signal;
a first n-channel transistor having a gate terminal configured to receive the input signal;
a second n-channel transistor having a gate terminal configured to receive the input signal;
wherein source-drain paths of the p-channel transistor, the first n-channel transistor and the second n-channel transistor are connected in series; and
wherein the second control signal is generated at drains of the p-channel transistor and the first n-channel transistor connected to the output of the high threshold control circuit.

12. The circuit of claim 11, wherein the high threshold control circuit further comprises a feedback transistor having a source-drain path connected between a power supply node and a node between the first n-channel transistor and the second n-channel transistor, said feedback transistor having a control terminal configured to receive the second control signal.

13. A method, comprising:
driving a gate terminal of an n-channel MOSFET with a first control signal;
driving a gate terminal of a p-channel MOSFET with a second control signal;
wherein drains of the n-channel MOSFET and the p-channel MOSFET are connected to an output node generating an output signal;
in response to a decrease in a voltage level of an input signal to be less than or equal to a low voltage trip point, changing a logic state of the first control signal; and
in response to an increase in the voltage level of the input signal to be greater than or equal to a high voltage trip point, changing a logic state of the second control signal.

14. The method of claim 13, wherein the high voltage trip point is greater than the low voltage trip point.

15. The method of claim 13, further comprising latching a logic state of the output signal.

16. The method of claim 13, wherein changing the logic state of the first control signal comprises changing the logic state of the first control signal from a first logic state to a second logic state when the voltage level of the input signal decreases to be less than or equal to the low voltage trip point; and further comprising:
changing the logic state of the second control signal from the first logic state to the second logic state when the voltage level of the input signal decreases to be less than or equal to a first voltage, said first voltage being greater than the low voltage trip point.

17. The method of claim 16, wherein the first logic state is logic low and the second logic state is logic high.

18. The method of claim 13, wherein changing the logic state of the second control signal comprises changing the logic state of the second control signal from a second logic state to a first logic state when the voltage level of the input signal increases to be greater than or equal to the high voltage trip point; and further comprising:
changing the logic state of the first control signal from the second logic state to the first logic state when the voltage level of the input signal increases to be greater than or equal to a second voltage, said second voltage being less than the high voltage trip point.

19. The method of claim 18, wherein the first logic state is logic low and the second logic state is logic high.

20. A circuit, comprising:
a low threshold control circuit comprising:
a first p-channel transistor having a gate terminal configured to receive an input signal;
a second p-channel transistor having a gate terminal configured to receive the input signal;
a first n-channel transistor having a gate terminal configured to receive the input signal;
wherein source-drain paths of the first p-channel transistor, the second p-channel transistor and the first n-channel transistor are connected in series; and
wherein a first control signal is generated at a first node that is connected to drains of the second p-channel transistor and the first n-channel transistor;
a high threshold control circuit comprising:
a third p-channel transistor having a gate terminal configured to receive the input signal;
a second n-channel transistor having a gate terminal configured to receive the input signal;
a third n-channel transistor having a gate terminal configured to receive the input signal;
wherein source-drain paths of the third p-channel transistor, the second n-channel transistor and the third n-channel transistor are connected in series; and
wherein the second control signal is generated at a second node connected to drains of the third p-channel transistor and the second n-channel transistor;
a fourth p-channel transistor having a source-drain path connected between a supply node and an output node, said fourth p-channel transistor having a control terminal configured to receive said second control signal; and
a fourth n-channel transistor having a source-drain path connected between the output node and a ground node, said fourth n-channel transistor having a control terminal configured to receive said first control signal.

21. The circuit of claim 20, further comprising a latch circuit having a first latch node connected to the output node.

22. The circuit of claim 21, wherein the latch circuit comprises:
a first inverter circuit having an input connected to the output node; and
a second inverter circuit having an output connected to the output node;
wherein an output of the first inverter circuit is connected to an input of the second inverter circuit.

23. The circuit of claim 20:
wherein the low threshold control circuit further comprises a first feedback transistor having a source-drain path connected between the ground node and a node between the first p-channel transistor and the second p-channel transistor, said first feedback transistor having a control terminal configured to receive the first control signal; and
wherein the high threshold control circuit further comprises a second feedback transistor having a source-drain path connected between the supply node and a node between the third n-channel transistor and the fourth n-channel transistor, said second feedback transistor having a control terminal configured to receive the second control signal.
